(19) United States
(12) Patent Application Publication
(10) Pub. No.: US 2007/0052094 A1
(43) Pub. Date: Mar. 8, 2007

(54) Semiconductor wafer level chip package and method of manufacturing the same

(75) Inventors: Goon-Woo Kim, Cheonan-si (KR); Man-Hee Han, Cheonan-si (KR); Jae-Hong Kim, Cheonan-si (KR); Heui-Seog Kim, Cheonan-si (KR); Sang-Jun Kim, Cheonan-si (KR); Wha-Su Sin, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/431,084

(22) Filed: May 10, 2006

(30) Foreign Application Priority Data
Aug. 26, 2005 (KR) 10-2005-0078722

(51) Int. Cl. H01L 23/48; H01L 21/44

(52) U.S. Cl. 257/737; 438/613; 257/E23.021

(57) ABSTRACT

A semiconductor chip package may include one or more conductive patterns provided on a front surface of a wafer. An encapsulation layer may cover at least the front surface of the wafer. Chip plugs may be electrically connected to the conductive patterns, and may be embedded in a rear surface of the wafer. External connection terminals may be electrically connected to the chip plugs, and may be provided on the rear surface of the wafer.

### PRIORITY STATEMENT

This application claims the benefit of Korean Patent Application No. 10-2005-0078722, filed on Aug. 26, 2005, in the Korean Intellectual Property Office, the disclosure of which is incorporated herein in its entirety by reference.

### BACKGROUND

1. Field of the Invention

Example embodiment of the present invention relate generally to a semiconductor package and a method of manufacturing the semiconductor package, and more particularly, to a semiconductor wafer level chip package and a method of manufacturing the same.

2. Description of the Related Art

Semiconductor chip packages may be manufactured on a wafer level (“wafer level packages”). According to a wafer level packaging process, the packages may be fabricated before separating the individual chips from the wafer. This may be in contrast to a packaging process in which the wafer is manufactured and divided into individual chips and then the individual chips may be assembled into packages.

FIG. 1 is a plan view of a conventional wafer level package 50, and FIG. 2 is a cross-sectional view taken along line II-II of FIG. 1. A conductive bump 29 is not illustrated in FIG. 1 for clarity.

Referring to FIGS. 1 and 2, the conventional wafer level package 50 may include a semiconductor chip 10 having a plurality of chip pads 12. The chip pads 12 may be disposed along an edge of an active area of a semiconductor substrate 11. The conventional wafer level package 50 may include a redistribution metal layer 23 that may contact an upper surface of the chip pads 12 and may be electrically connected to the conductive bump 29. In this way, the redistribution metal layer 23 may reroute the chip pads 12. The conductive bump 29 may be attached to a bump land pad 25 of the redistribution metal layer 23.

The chip pads 12 may be electrically connected to a conductive pattern 15 on the semiconductor substrate 11. A passivation layer 13 may cover the conductive pattern 15 and portions of the chip pads 12. The chip pads 12 may be fabricated from aluminum (for example), and the passivation layer 13 may be an oxide layer, a nitride layer, or a combination layer thereof (for example). A first insulating layer 22 may be provided on the passivation layer 13 so as to expose the chip pads 12. The first insulating layer 22 may be a polyimide layer (for example).

The redistribution metal layer 23 may be connected to the chip pads 12, and may be provided on the first insulating layer 22. The bump land pad 25, which may have circular shape (for example), may support the conductive bump 29 The conductive bump 29 may have a ball shape (for example). A second insulating layer 27 may be provided on the surface of the semiconductor chip 10 except for the portion of the bump land pad 25. The conductive bump 29 may be placed on the bump land pad 25, and a solder reflow process may be performed to bond the conductive bump 29 to the bump land pad 25. An under bump metal (UBM) layer 20 may be provided on the chip pads 12 and the first insulating layer 22. The redistribution metal layer 23 may be provided on the UBM layer 20.

Although the conventional structure is generally thought to provide acceptable performance, it is not without shortcomings. For example, the conductive bumps 29 and the conductive patterns 15 may be provided on the same side of the semiconductor substrate 11. A rear surface of the wafer may be exposed during an assembling and mounting process of the package, and thus, a part of the semiconductor chip 10 may be chipped and/or cracked due to external shock (for example). In addition, the conductive pattern 15 may be damaged due to the stress generated when the redistribution metal layer 23 and the bump land pad 25 are formed and/or the stress generated when performing the reflow process. Moreover, the stress (which may be generated during use of the package) in a connection portion of conductive bumps may affect the neighboring conductive patterns 15.

### SUMMARY

According to an example, non-limiting embodiment, a semiconductor wafer level chip package may include a wafer having a front surface and a rear surface. A conductive pattern may be provided on the front surface of the wafer. An encapsulation layer may cover at least the front surface of the wafer. Chip plugs may be electrically connected to the conductive patterns, and may be embedded in the rear surface of the wafer. External connection terminals may be electrically connected to the chip plugs, and may be provided on the rear surface of the wafer.

According to another example, non-limiting embodiment, a method of manufacturing a semiconductor wafer level chip package may involve providing a conductive pattern on a front surface of a wafer. Chip plugs that may be electrically connected to the conductive patterns may be embedded in a rear surface of the wafer. At least a front surface of the wafer may be covered with an encapsulation layer. External connection terminals may be provided on the rear surface of the wafer so that the external connection terminals are electrically connected to the chip plugs.

According to another example, non-limiting embodiment, a package may include a wafer having a front surface and a rear surface. A conductive pattern may be provided on the front surface of the wafer. An encapsulation layer may cover the front surface of the wafer. A chip plug may be electrically connected to the conductive patterns, and may be extended into the wafer. An external connection terminal may be electrically connected to the chip plug, and may be provided on the rear surface of the wafer.

### BRIEF DESCRIPTION OF THE DRAWINGS

Example, non-limiting embodiments of the present invention will be described with reference to the attached drawings.

FIG. 1 is a plan view of a wafer level package according to the conventional art.

FIG. 2 is a cross-sectional view taken along line II-II of FIG. 1.

FIGS. 3 through 10 are cross-sectional views of a method that may be implemented to manufacture a wafer level package according to an example, non-limiting embodiment of the present invention.

FIGS. 11 through 13 are cross-sectional views of a method that may be implemented to manufacture a wafer level package according to another example, non-limiting embodiment of the present invention.

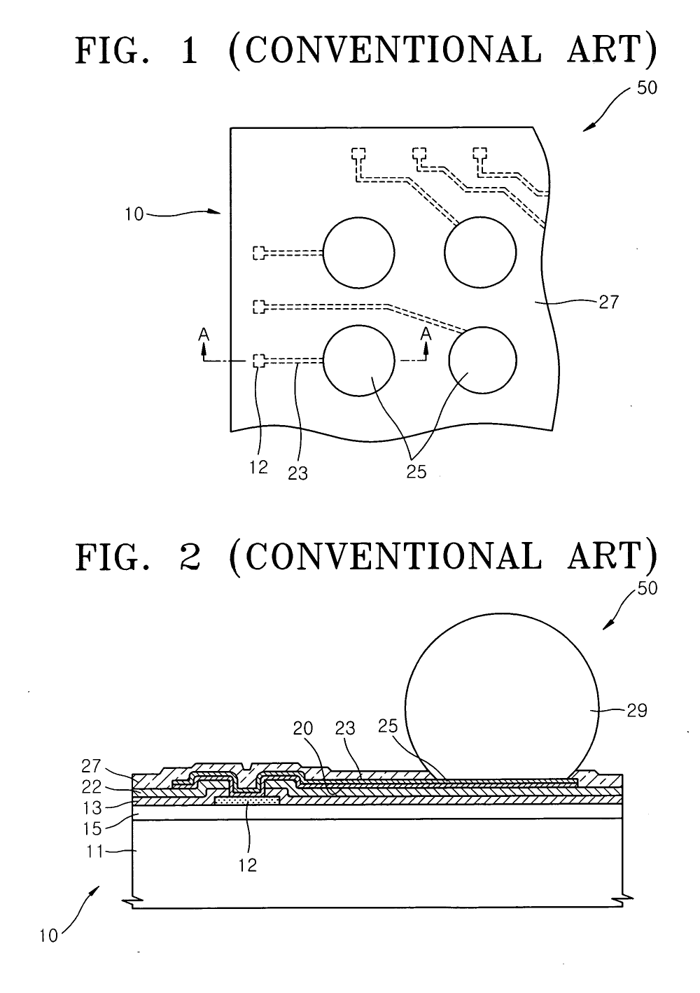

The drawings are provided for illustrative purposes only and are not drawn to scale. The spatial relationships and relative sizing of the elements illustrated in the various embodiments may be reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to example embodiments of the invention. Like reference numerals in the drawings denote like elements, and thus their description may be omitted.

### DETAILED DESCRIPTION OF EXAMPLE, NON-LIMITING EMBODIMENTS

Example, non-limiting embodiments of the present invention will be described with reference to the accompanying drawings. The invention may, however, be embodied in many different forms and should not be construed as being limited to the embodiments set forth herein; rather, the disclosed embodiments are provided so that this disclosure will be thorough and complete, and will fully convey the concept of the invention to those skilled in the art.

Well-known structures and processes are not described or illustrated in detail to avoid obscuring the present invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

According to example, non-limiting embodiments of the present invention, a “front surface” of a wafer may be a surface supporting conductive patterns, and a “rear surface” of the wafer may be a surface opposite to the front surface. Example, non-limiting embodiments of the present invention may provide a method of encapsulating the conductive patterns to protect the same, for example. In addition, the example, non-limiting embodiments of the present invention may provide external connection terminals for wiring, for example, conductive bumps on the rear surface of the wafer. Varied and alternative shapes of chip plugs that may be used to electrically connect the conductive patterns to the conductive bumps will be described in the example, non-limiting embodiments of the present invention.

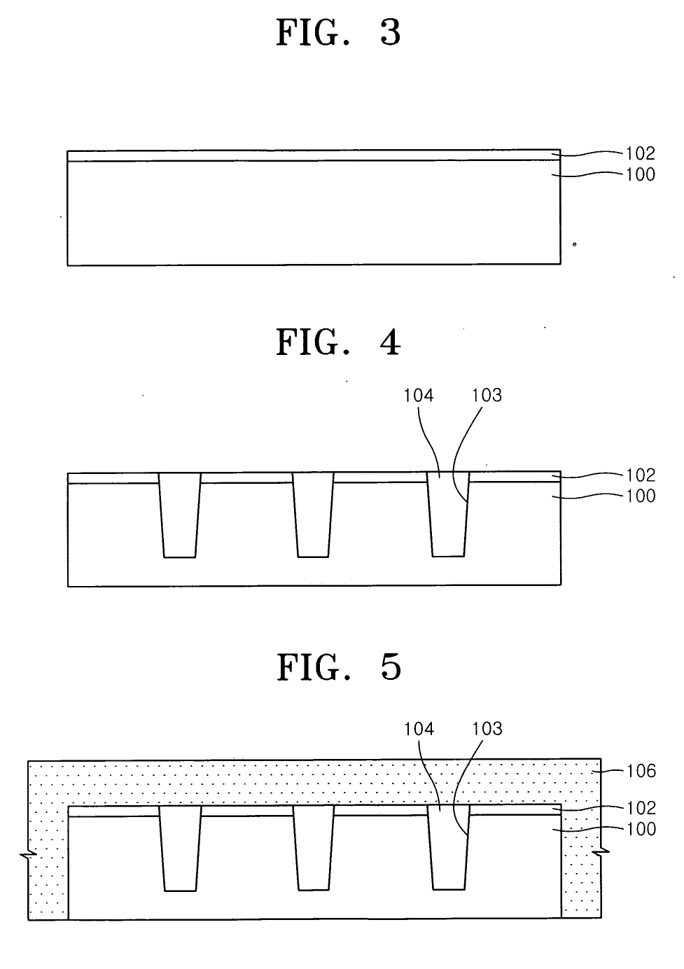

FIGS. 3 through 10 are cross-sectional views of a method that may be implemented to manufacture a wafer level package according to an example, non-limiting embodiment of the present invention.

Referring to FIG. 3, at least one conductive pattern 102 may be provided on a front surface of a wafer 100. The conductive pattern 102 may be provided in a multi-interlayer dielectric structure. Although it is not shown in FIG. 3, the uppermost conductive pattern 102 may extend to edges of a semiconductor chip to be connected to first chip plugs (104 in FIG. 4).

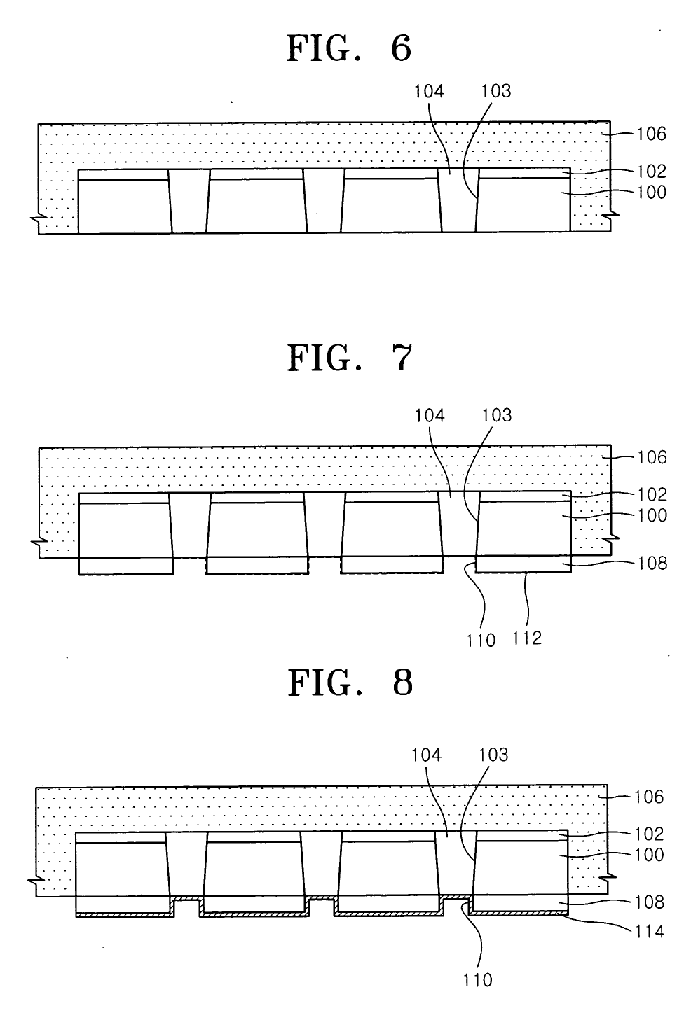

Referring to FIG. 4, first via holes 103 may be provided through the uppermost conductive pattern 102. The first via holes 103 may extend into the wafer 100. The recessed depth of the first via holes 103 may be determined by the desired exposure of the first chip plugs 104 when a back lapping process is performed as shown in FIG. 6. The first via holes 103 may be provided using a laser drill method and/or a plasma etching method, for example. Inner walls of the first via holes may be coated with barrier metal layers (not shown). The barrier metal layers may be provided via a sputtering method and/or an evaporation method, for example. The barrier metal layers may be electrically connected to the conductive pattern 102. The barrier metal layers may be fabricated from titanium, titanium nitride, titanium/tungsten, a platinum/silicon, aluminum, and/or alloy thereof, for example.

First chip plugs 104 may be provided by embedding a conductive metal in the first via holes 103. The conductive metal forming the first chip plugs 104 may be a metal having a good electrical conductivity property, for example, copper, gold, and/or tungsten.

Referring to FIG. 5, an encapsulation layer 106 may be provided on the front surface and side surfaces of the wafer 100. The encapsulation layer 106 may be fabricated from an epoxy molding compound, for example. In alternative embodiments, the encapsulation layer may be fabricated from numerous and varied materials that are well known in this art. In alternative embodiments, the encapsulation layer 106 may be provided on the front surface only of the wafer 100. However, providing the encapsulation layer 106 on the side surfaces of the wafer 100 may inhibit an infiltration of impurities into the conductive pattern 102. The encapsulation layer 106 may protect a part of the wafer 100 from being chipped and/or cracked during the processes of assembling the package and mounting the package. In addition, the encapsulation layer 106 may protect the conductive pattern 102 from being damaged due to the stress generated when a redistribution metal layer (114 of FIG. 8) and/or bump supports (122 of FIG. 10) are formed.

Referring to FIG. 6, a thickness of the rear surface of the wafer 100 may be removed using a back lapping process (for example) to expose the first chip plugs 104. By way of example only, the wafer 100 may have an 8-inch diameter, the thickness of the wafer 100 may be about 720 μm before performing the back lapping process, and the wafer 100 may be back lapped to a thickness of about 20 μm-80 μm. In general, the wafer 100 may be back lapped to a thickness of about 50 μm. However, because the wafer 100 may be supported by the encapsulation layer 106, the wafer 100 may be back lapped to a thickness of about 50 μm or less. When the wafer 100 is thin, the multi-layer wafer level package may be highly concentrated. In alternative embodiments, the thickness of the wafer 100 may be reduced using a chemical mechanical polishing (CMP) process, a wet-etching process, and/or a dry-etching process, for example.

Referring to FIG. 7, a first insulating layer 108, which may include first contact holes 110 that expose the first chip plugs 104, may be provided on the rear surface of the wafer 100. The first insulating layer 108 may be an oxide layer, a nitride layer, and/or a combination layer thereof, for example. The first contact holes 110, which may expose the first chip plugs 104, may be formed using a photolithography process, for example. To form the redistribution metal layer 114, a seed layer 112 may be provided on the first chip plugs 104 and the first insulating layer 108 using a sputtering method and/or an evaporation method, for example. The seed layer 112 may be fabricated from a conductive metal, and may be attached to the redistribution metal layer 114 to perform a plating process. The seed layer 112 may be a titanium layer, a titanium nitride layer, a titanium/tungsten layer, a platinum/silicon layer, an aluminum layer, and/or alloy layer thereof, for example.

Referring to FIG. 8, the redistribution metal layer 114 may be provided on the seed layer 112 using a plating method, for example. The redistribution metal layer 114 may provide a region where external connection terminals (124 of FIG. 10) may be provided.

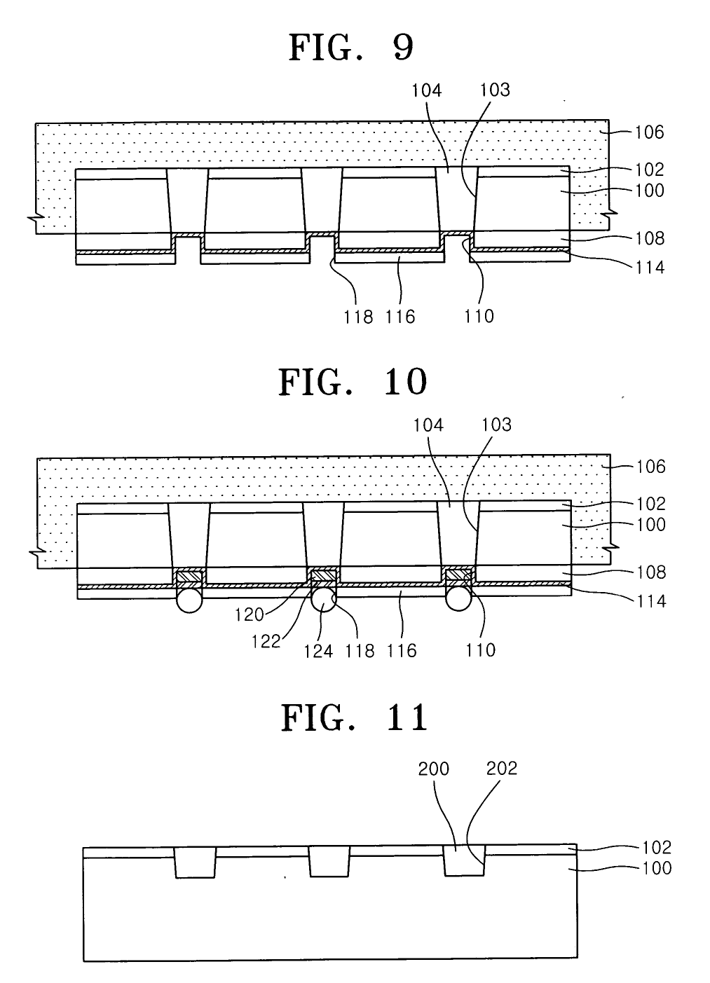

Referring to FIG. 9, a second insulating layer 116, which may include second contact holes 118 that may expose the redistribution metal layer 114 on the first chip plugs 104, may be provided using a conventional process that is well known in this art. The second insulating layer 116 may be an oxide layer, a nitride layer, and/or a combination layer thereof, for example. The second contact holes 118 may expose the redistribution metal layer 114 on the first chip plugs 104, and may be provided using a photolithography process (for example) that is well known in this art. The second contact holes 118 may provide bump land regions on which external connection terminals such as conductive bumps (for example) may be provided.

Referring to FIG. 10, an under bump metal (UBM) layer 120 may be provided to fill a portion of the second contact holes 118. The UBM layer 120 may be provided using a plating method (for example), and may be fabricated from titanium, a titanium nitride material, titanium carbide, and/or stacked layers thereof (for example). Bump supports 122 may be provided on the UBM layer 120 using a conventional electric plating method and/or a solder paste printing method, both of which are well known in this art. External connection terminals 124, for example, conductive bumps, may be mounted on the bump supports 122. In an example embodiment, the conductive bumps 124 may be in the form of solder balls, for example. The conductive bumps 124 may be attached to the bump supports 122 via a conventional reflow process that is well known in this art. The wafer 100 may be cut into a plurality of semiconductor chips.

The encapsulation layer 106 may protect the conductive patterns 102 on the wafer 100. The redistribution metal layer 114 and the external connection terminals 124 may be provided on the rear surface of the wafer 100. The above structure may reduce the chances of some parts of the wafer 100 becoming chipped and/or cracked during the assembling and mounting processes of the package. In addition, the structure may reduce the chances of the conductive pattern 102 becoming damaged by the stress generated when forming the redistribution metal layer 114 and/or the bump supports 122 and/or the thermal stress generated during the reflow process associated with the external connection terminals 124, such as the conductive bumps, for example. Moreover, the external connection terminals 124 may be provided on the rear surface of the wafer 100 and apart from the conductive pattern 102. Accordingly, the effect on the conductive pattern 102 due to the stress generated on connection portions of the external connection terminals 124 may be reduced. Marks for dividing the wafer level packages may be provided on the encapsulation layer 106.

FIGS. 11 through 13 are cross-sectional views illustrating a method that may be implemented to manufacture a wafer level package according to another example, non-limiting embodiment of the present invention. Processes implemented to provide contact holes 204 on a rear surface of the wafer 100 to contact second chip plugs 200 and processes implemented to provide external connection terminals may be the same as those of the example embodiment illustrated in FIGS. 7 through 10. Accordingly, a detailed description thereof will be omitted.

Referring to FIG. 11, at least one conductive pattern 102 may be provided on a front surface of the wafer 100. The conductive pattern 102 may be provided in multi-interlayer dielectric structure. Although it is not shown in the drawings, the uppermost conductive pattern 102 may extend to edges of a semiconductor chip to be connected to second chip plugs 200.

Second via holes 202 may be provided through the uppermost conductive pattern 102. The second via holes 202 may extend into the wafer 100. The second via holes 202 may be recessed so that the second chip plugs 200 may not be exposed when a back lapping process is performed. The second via holes 202 may be provided using a laser drill method and/or a plasma etching method, for example. Barrier metal layers (not shown) may be provided on inner walls of the second via holes 202 using a sputtering method and/or an evaporation method, for example. The barrier metal layers may be electrically connected to the conductive pattern 102. The barrier metal layers may be fabricated from titanium, titanium nitride, titanium/tungsten, platinum/silicon, aluminum, and/or an alloy thereof, for example.

The second chip plugs 200 may be provided by embedding a conductive metal in the second via holes 202. The conductive metal forming the second chip plugs 200 may be a metal having a good electrical conductivity property, for example, copper, gold, and/or tungsten.

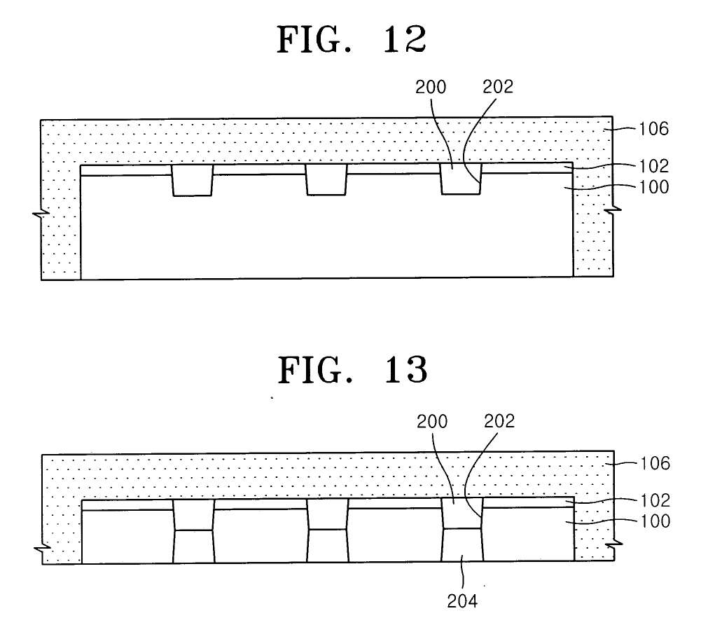

Referring to FIG. 12, an encapsulation layer 106 may be provided on the front surface and side surfaces of the wafer 100. The encapsulation layer 106 may be fabricated from an epoxy molding compound, for example. In alternative embodiments, the encapsulation layer 1 may be fabricated from numerous and varied materials that are well known in this art. In alternative embodiments, the encapsulation layer 106 may be provided on the front surface only of the wafer 100. However, providing the encapsulation layer 106 on the side surfaces of the wafer 100 may inhibit an infiltration of impurities into the conductive pattern 102. The encapsulation layer 106 may protect a part of the wafer 100 from being chipped and/or cracked during the processes of assembling and mounting the package. In addition, the encapsulation layer 106 may protect the conductive pattern 102 from being damaged due to the stress generated when a redistribution metal layer (114 of FIG. 8) and/or bump supports (122 of FIG. 10) are formed.

Referring to FIG. 13, a thickness of the rear surface of the wafer 100 may be removed using the back lapping process (for example). By way of example only, the wafer may have an 8-inch diameter, the thickness of the wafer 100 may be about 720 μm before performing the back lapping process, and the wafer 100 may be back lapped to a thickness of about 20 μm-80 μm. In general, the wafer 100 may be back lapped to a thickness of about 50 μm. However, because the wafer 100 may be supported by the encapsulation layer 106, the wafer 100 may be back lapped to a thickness of about 50 μm or less. When the wafer 100 is thin, the multi-layer wafer level package may be highly concentrated. In alternative embodiments, the thickness of the wafer 100 may be reduced using a CMP process, a wet-etching process, and/or a dry-etching process, for example.

In this example embodiment, the second chip plugs 200 may not be exposed on the rear surface of the wafer 100. Rear surface contacts 204 may be provided on the wafer 100. The rear surface contacts 204 may be electrically connected to the second chip plugs 200, and exposed on the rear surface of the wafer 100.

According to the present embodiment, the conductive pattern 102 of the wafer 100 may be protected by the encapsulation layer 106. The redistribution metal layer 114 and the external connection terminals (124 of FIG. 10) may be provided on the rear surface of the wafer 100. The above structure may reduce the chances of some parts of the wafer 100 becoming chipped and/or cracked during the assembling and mounting processes of the package. In addition, the structure may reduce the chances of the conductive pattern 102 being damaged by stress generated when forming the redistribution metal layer 114 and/or bump supports 122 and/or the thermal stress generated during the reflow process associated with the external connection terminals 124, such as the conductive bumps (for example). Moreover, the external connection terminals 124 may be provided on the rear surface of the wafer 100 and apart from the pattern 102. Accordingly, the effect on the conductive pattern 102 due to the stress generated on connection portions of the external connection terminals 124 may be reduced. Additionally, marks for dividing the packages may be provided on the encapsulation layer 106.

According to the example, non-limiting embodiments of the present invention, external connection terminals may be provided on a rear surface of a wafer, and a front surface of the wafer may be covered by an encapsulation layer. Thus, a conductive pattern may be protected during processes of package assembly, mounting the package, and forming the external connection terminals.

In addition, a back lapping process, may be performed when the wafer may be supported by the encapsulation layer, and thus, the thickness of the wafer may be thinned more, as compared to conventional devices.

The present invention has been shown and described with reference to example, non-limiting embodiments. It will be understood by those of ordinary skill in the art that various changes in form and details may be suitably implemented without departing from the spirit and scope of the present invention as defined by the following claims.

What is claimed is:

1. A semiconductor wafer level chip package comprising:
a wafer having a front surface and a rear surface;
a conductive pattern provided on the front surface of the wafer;
an encapsulation layer covering at least the front surface of the wafer;
chip plugs electrically connected to the conductive pattern, and embedded in the rear surface of the wafer; and
external connection terminals electrically connected to the chip plugs, and provided on the rear surface of the wafer.

2. The semiconductor chip package of claim 1, wherein the conductive pattern is directly connected to the chip plugs.

3. The semiconductor chip package of claim 1, wherein the encapsulation layer covers the front surface and side surfaces of the wafer.

4. The semiconductor chip package of claim 1, wherein the encapsulation layer is fabricated from an epoxy molding compound.

5. The semiconductor chip package of claim 1, wherein the wafer has a thickness of 20 μm-80 μm.

6. The semiconductor chip package of claim 1, wherein the chip plugs are exposed on the rear surface of the wafer.

7. The semiconductor chip package of claim 1, wherein the chip plugs are connected to rear contacts and the rear contacts are exposed on the rear surface of the wafer.

8. The semiconductor chip package of claim 1, further comprising:
a redistribution metal layer provided between the chip plugs and the external connection terminals.

9. The semiconductor chip package of claim 1, wherein the external connection terminals are solder balls.

10. A method of manufacturing a semiconductor wafer level chip package, the method comprising:
providing a conductive pattern on a front surface of a wafer;
embedding chip plugs that are electrically connected to the conductive patterns in a rear surface of the wafer;
covering at least a front surface of the wafer with an encapsulation layer; and
providing external connection terminals on the rear surface of the wafer so that the external connection terminals are electrically connected to the chip plugs.

11. The method of claim 10, wherein embedding the chip plugs comprises:
forming first via holes through the conductive pattern and into the wafer; and
placing a conductive material in the first via holes.

12. The method of claim 10, wherein the encapsulation layer covers the front surface and side surfaces of the wafer.

13. The method of claim 10, further comprising back lapping the rear surface of the wafer before providing the external connection terminals.

14. The method of claim 13, wherein the wafer is back lapped to a thickness of about 20 μm-80 μm.

15. The method of claim 13, wherein the chip plugs are exposed on the rear surface of the wafer after back lapping.

16. The method of claim 13, further comprising:
forming contact holes in the rear surface of the wafer to expose the chip plugs; and
filling a conductive material in the contact holes to form rear contacts.

17. The method of claim 10, further comprising:
providing a redistribution metal layer between the chip plugs and the external connection terminals.

18. The method of claim 17, further comprising:
back lapping the rear surface of the wafer to expose the chip plugs;
covering the entire rear surface of the wafer with a first insulating layer;
forming first contact holes in the first insulating layer to expose the chip plugs; and
forming a seed layer for forming the redistribution metal layer on the exposed chip plugs and the first insulating layer.

19. The method of claim 17, further comprising:
performing a lapping process on the rear surface of the wafer;
forming contact holes in the rear surface of the wafer to expose the chip plugs;
filling a conductive material in the contact holes to form rear contacts;
forming a first insulating layer covering the entire rear surface of the wafer;
forming first contact holes in the first insulating layer to expose the chip plugs; and
forming a seed layer for forming the redistribution metal layer on the exposed chip plugs and the first insulating layer.

20. A package comprising:
a wafer having a front surface and a rear surface;
a conductive pattern provided on the front surface of the wafer;
an encapsulation layer covering the front surface of the wafer;
a chip plug electrically connected to the conductive pattern, and extended into the wafer; and
an external connection terminal electrically connected to the chip plug, and provided on the rear surface of the wafer.
